(19) United States
(12) Patent Application Publication
(10) Pub. No.: US 2010/0148095 A1
(43) Pub. Date: Jun. 17, 2010

(54) STAMPER, STAMPER TESTING METHOD, AND STAMPER TESTING APPARATUS

(75) Inventors: Kazuyo Umezawa, Yokohama-shi (JP); Seiji Morita, Yokohama-shi (JP); Masatoshi Sakurai, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/538,638

(22) Filed: Aug. 10, 2009

(30) Foreign Application Priority Data
Dec. 12, 2008 (JP) 2008-317008

(51) Int. Cl. H01L 33/00; B29C 35/08

(52) U.S. Cl. 250/552; 425/174.4

(57) ABSTRACT

According to one embodiment, a stamper has a data area and servo area, and has concentric or spiral grooves formed in the data area. Phases αE and αH at which differential signal levels of the E- and H-polarized light are maximum when the data area is irradiated with a laser beam have a relationship represented by

(αE+αH)≦270°

### CROSS-REFERENCE TO RELATED APPLICATIONS

This application is based upon and claims the benefit of priority from Japanese Patent Application No. 2008-317008, filed Dec. 12, 2008, the entire contents of which are incorporated herein by reference.

### BACKGROUND

1. Field

One embodiment of the present invention relates to a stamper for transferring three-dimensional track patterns onto a recording medium, a stamper testing method, and a stamper testing apparatus.

2. Description of the Related Art

Recently, as the recording density of an information recording medium increases, marks to be recorded on the medium are becoming finer. To facilitate the formation of fine recording marks, a demand has arisen for a micropatterning technique of forming three-dimensional patterns of about 100 nm or less on a recording medium. As the micropatterning technique like this, a method of combining the formation of fine patterns by lithography such as electron beam (EB) lithography or focused ion beam (FIB) lithography and the transfer of the fine patterns onto a medium substrate by nano-imprint lithography (NIL) is being studied.

On the other hand, as a medium technique for increasing the recording density, a magnetic recording system using a discrete track recording (DTR) medium having a data area and servo area is known as disclosed in, e.g., Jpn. Pat. Appln. KOKAI Publication No. 2004-110896.

Also, optical disks such as a Compact Disc (CD) and Digital Versatile Disc (DVD) are similarly required to have large capacities, and the development of multilayered optical disks is advancing. A method of manufacturing the multilayered optical disk is disclosed in, e.g., Jpn. Pat. Appln. KOKAI Publication No. 2003-281791. In this method, a transparent resin substrate formed from an Ni stamper by injection molding and a transparent resin stamper similarly formed by injection molding are bonded via a 2P(photopolymer) resin, and the 2P resin is cured by ultraviolet (UV) radiation. After that, patterns are transferred by separating the transparent stamper, and a multilayered medium film having a thickness of a few tens of micrometers is formed on the transferred patterns.

At the same time the recording density of an information recording medium is increased, it is necessary to ensure high signal intensity even for a small bit. For this purpose, it is very important not only to improve the characteristics of a magnetic recording film itself, but also to optimize the groove shape of a stamper to be used in transfer.

As disclosed in, e.g., Jpn. Pat. Appln. KOKAI Publication No. 2008-159196, a method of measuring the Kerr rotation angle is being examined as a method of checking the groove depth of an information recording medium (see, e.g., patent reference 3). However, the groove shape of an information recording medium reflects that of a stamper. Therefore, it is more effective to check the groove shape before the formation of an information recording medium from the viewpoint of process management as well.

Also, the groove shape of an information recording medium have conventionally been evaluated by an atomic force microscope (AFM) or scanning electron microscope (SEM). However, the AFM or SEM performs measurement in a very narrow field, and is hardly capable of measurement in a wide region.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIGS. 1A to 1F are views for explaining an example of a DTR medium manufacturing method according to the present invention;

FIG. 2 is a block diagram showing an outline of the arrangement of a stamper testing apparatus according to the present invention;

FIGS. 3A to 3D are views for explaining a method of forming a magnetic recording medium by means of a stamper of the present invention;

FIGS. 4A to 4D are views for explaining the method of forming a magnetic recording medium by means of the stamper of the present invention;

FIG. 5 is a view showing a magnetic recording/reproduction apparatus;

FIG. 6 is a graph showing the relationship between the sum of αE and αH and the bit error rate;

FIGS. 7A to 7D are model views showing the sections of various groove shapes; and

FIG. 8 is a graph showing the results of stamper groove shape evaluation performed on the stampers shown in FIGS. 7A to 7D.

### DETAILED DESCRIPTION

Various embodiments according to the invention will be described hereinafter with reference to the accompanying drawings. In general, according to one embodiment of the invention, a stamper has concentric or spiral three-dimensional patterns for forming track patterns on the surface of a recording layer of a recording medium having a data area and servo area. The sum of phases αE and αH at which a differential signal level of E- and H-polarized light components of reflected light is maximum when the three-dimensional patterns of the stamper, which correspond to the data area of the recording medium, are irradiated, by means of a laser beam, with the E-polarized component of linearly polarized light, i.e., the E-wave corresponding to an electromagnetic wave having an electric field E parallel to the incident surface and the H-polarized component of linearly polarized light, i.e., H-wave corresponding to an electromagnetic wave having a magnetic field H parallel to the incident surface has a relationship represented by (αE+αH)≦270°.

Also, a stamper testing method of the present invention is an example of a testing method to be used to obtain the above-mentioned stamper. The method includes irradiating a data portion of the stamper with the E- and H-polarized components of linearly polarized light by means of a semiconductor laser, and measuring the voltage of a differential signal of the reflected light by changing the phase. The method further includes obtaining phases αE and αH at which difference signal voltages of the E- and the H-polarized light are maximum, and determining the quality of a groove shape from the sum (αE+αH).

Furthermore, a stamper testing apparatus of the present invention is an example of a testing apparatus to be used to obtain the above-mentioned stamper, and is an apparatus for testing the groove shape of concentric or spiral three-dimensional patterns formed on a stamper for forming track patterns on the surface of a recording layer of a recording medium having a data area and servo area. This apparatus is characterized by including a measurement unit which irradiates a data portion of the stamper with the E- and H-polarized components of linearly polarized light by means of a semiconductor laser, and measures the voltage of a differential signal of the reflected light by changing the phase, and a determination unit which obtains phases αE and αH at which difference signal voltages of the E- and H-polarized light are maximum respectively, and determines the quality of the groove shape from the sum (αE+αH).

The present invention provides a stamper in which the sum of the phases αE and αH at which the differential signal voltage of the reflected E- and H-polarized light is maximum satisfies αE+αH≦270°. This makes it possible to manage an optimum uniform groove shape.

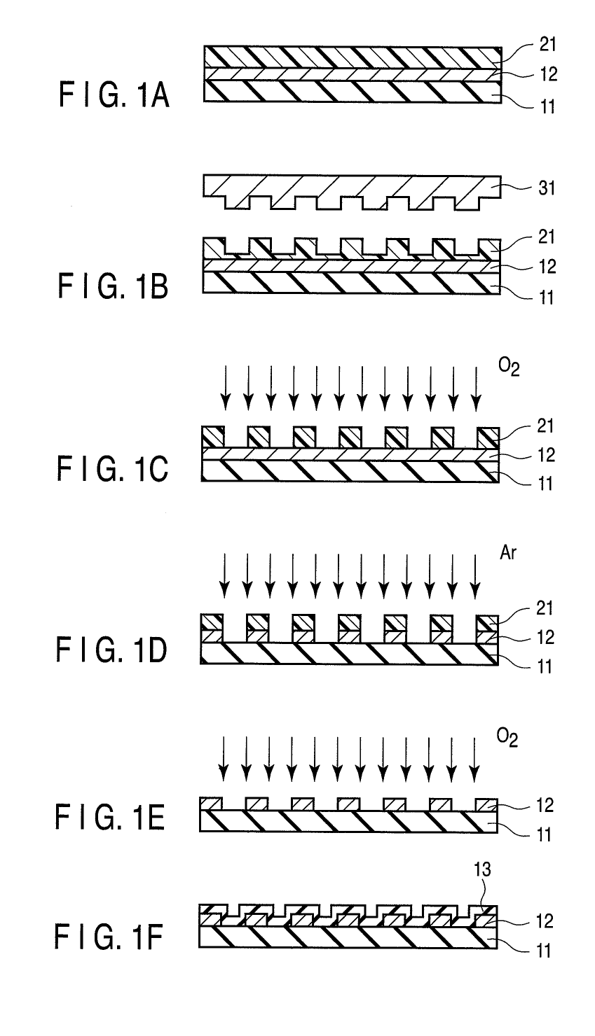

FIGS. 1A to 1F are views for explaining an example of a DTR medium manufacturing method according to the present invention.

First, as shown in FIG. 1A, a magnetic layer 12 is formed on a substrate 11 and coated with a resist 21. Subsequently, as shown in FIG. 1B, the pattern surface of a stamper 31 having three-dimensional patterns is opposed to the resist 21, and the patterns of the stamper 31 are transferred onto the resist 21 by imprinting. After that, as shown in FIG. 1C, a resist residue remaining in recesses of the resist 21 is removed by reactive ion etching using gaseous oxygen. Furthermore, as shown in FIG. 1D, the patterned resist 21 is used as a mask to etch the magnetic layer 12 by ion milling. As shown in FIG. 1E, the residual resist 21 is removed by oxygen ashing. A nonmagnetic material (not shown) is buried in the recesses as needed, and a protective film 13 is formed on the entire surface as shown in FIG. 1F. In this manner, a DTR medium is manufactured.

Imprinting is roughly classified into three types, i.e., thermal imprinting, high-pressure imprinting, and optical imprinting. Among these methods, optical imprinting using UV light is particularly superior in transfer properties and cost.

A method of reproducing information from the data area of the stamper will be explained below.

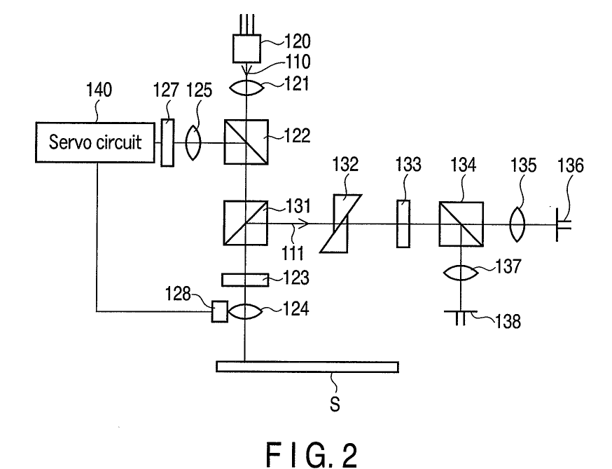

FIG. 2 is a block diagram showing an outline of the arrangement of a stamper testing apparatus for checking the groove shape characteristics by reproducing information from the data area of the stamper.

As shown in FIG. 2, the stamper is made of, e.g., Ni. A semiconductor laser source 120 is used as a light source. The wavelength of the exit light is, e.g., a violet wavelength band in the range of 400 to 410 nm. Exit light 110 from the semiconductor laser source 120 is collimated into parallel light by a collimator lens 121, and this parallel light enters an objective lens 124 through a beam splitter 122, polarizing beam splitter 131, and λ/2 plate 123. After that, the light is concentrated on that surface of a substrate of a stamper S, in which the grooves are formed. The numerical aperture must be 0.85 or more. If the numerical aperture is smaller than that, an aberration correcting plate must be inserted between the grooves and objective lens. Reflected light 111 from the groove surface of the stamper S is transmitted through the substrate of the stamper S again, transmitted through the objective lens 124 and λ/2 plate 123, and reflected by the polarizing beam splitter 131. After that, the reflected light 111 is transmitted through a phase compensation plate 132 and λ/2 plate 133, and split into two light components by a polarizing beam splitter 134. These two light components respectively enter photodetectors CH1 136 and CH2 138 through condenser lenses 135 and 137. The λ/2 plate 123 can switch E- and H-polarized light, and the phase compensation plate 132 can change the phase. Currents output on the basis of the light components received by the photodetectors CH1 and CH2 are converted into voltages by I/V amplifiers (current-voltage converters) (not shown). After that, a sum signal (CH1+CH2) and a differential signal (CH1−CH2) are output by performing arithmetic operations on these voltages. The groove shape is evaluated by means of these signals.

Also, the reflected light transmitted through the polarizing beam splitter 131 passes through the beam splitter 122, and enters a photodetector 127 through a condenser lens 125. A light-receiving unit of the photodetector 127 is normally divided into a plurality of portions, and each light-receiving portion outputs a current corresponding to the light intensity. The output current is converted into a voltage by an I/V amplifier (current-voltage converter) (not shown), and the voltage is input to a servo circuit 140. The servo circuit 140 performs an arithmetic operation on the input voltage signal, thereby generating a tilt error signal, HF signal, focusing error signal, and tracking error signal. The tilt error signal is used to perform tilt control. The focusing error signal is used to perform focusing control. The tracking error signal is used to perform tracking control.

The objective lens 124 can be driven in the vertical direction, disk radial direction, and tilt direction (the radial direction or/and tangential direction) by an actuator 128, and is controlled to follow information tracks on the stamper S by a servo driver 150.

Note that in this evaluation apparatus, the wavelength of the semiconductor laser is in the range of 400 to 410 nm as an example. However, the present invention is not limited to this, and the wavelength can also be shorter. Since the spot diameter of the laser is determined by λ/NA, a signal having higher resolution can be obtained at a shorter wavelength. Information can be reproduced from the stamper of the present invention by using the stamper testing apparatus as described above.

A stamper testing method will now be explained.

A stamper is set in the testing apparatus, and rotated at a linear velocity of 1.2 m/s.

A laser is emitted, and tilt and focusing offset are adjusted such that the voltage of the sum signal (CH1+CH2) is maximum. For the E- and H-polarized light, the phases αE and αH by which the voltage of the differential signal (CH1−CH2) is maximum are found by adjusting the phase compensation plate. Whether the groove shape is close to an expected value is tested by calculating (αE+αH).

In the present invention, the sum (αE+αH) of the phases αE and αH by which the difference signal voltages of the E- and H-polarized light are maximum is 270° or less. This makes it possible to manage an optimum uniform groove shape, and obtain an information recording medium having good recording characteristics.

The present invention will be explained in more detail below by way of its examples.

In the following examples, resin stampers formed by injection molding using several Ni stampers were used to transfer three-dimensional patterns onto ultraviolet-curable resin layers applied on medium substrates, thereby manufacturing DTR magnetic recording media.

A DTR magnetic recording medium has a plurality of servo areas, and a plurality of data areas divided by these servo areas. A preamble portion, address portion, and burst portion are formed in each servo area. Discrete tracks are formed in each data area.

Note that each figure is an exemplary view for explaining the invention and facilitating understanding of the explanation, and the shapes, dimensions, ratios, and the like are different from actual ones. However, the shapes, dimensions, ratios, and the like can be appropriately changed in consideration of the following explanation and well-known techniques.

First, a medium manufacturing method common to each example and a comparative example will be described below.

A transparent stamper was manufactured by the following method.

First, a master was coated with a resist, and a servo area and data area were written by electron beam lithography, thereby forming a resist master. A positive resist was used as the resist, and the thickness of the resist was set to 50 nm. Three-dimensional patterns corresponding to discrete tracks in the data area had a track pitch (TP) of 78 nm.

An Ni stamper for injection molding was manufactured by performing electro forming on the resist master. Note that as the Ni stamper, it is possible to use any of a so-called father stamper initially manufactured from the master; a mother stamper duplicated from the father stamper by electro forming; and a son stamper duplicated from the mother stamper by electro forming.

One Ni stamper was used to manufacture transparent resin stampers A to D by injection molding. Polycarbonate (PC) can be used as the material of the transparent stampers. When the releasability to a 2P resin is taken into consideration, however, it is possible to use, e.g., a cycloolefin polymer (COP), a cycloolefin copolymer (COC), or polymethylmethacrylate (PMMA). It is also possible to mix an organic compound containing a fluorine substituent or silicon as a releasing agent in each material.

Note that in the present invention, a cycloolefin polymer was used as the material of the transparent stampers.

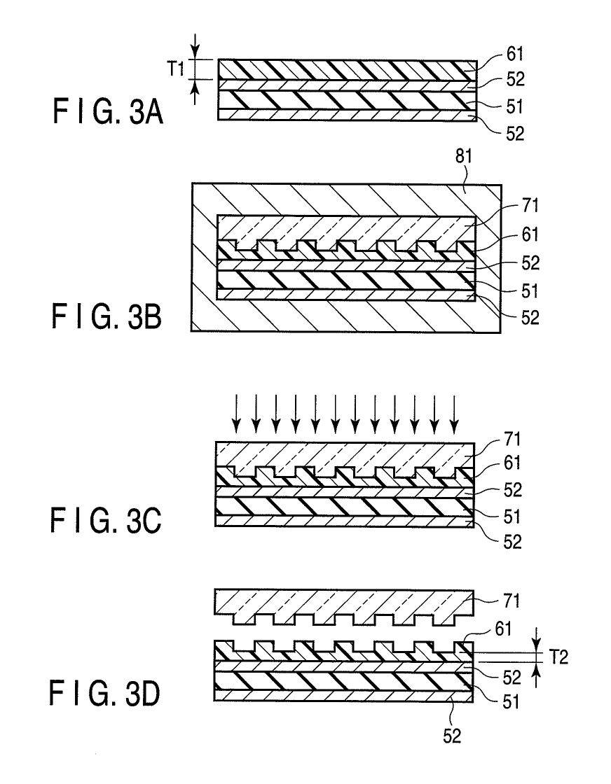

FIGS. 3A to 3D are views for explaining a method of forming a magnetic recording medium by using the stamper of the present invention.

As shown in FIG. 3A, magnetic layers 52 were formed on the two surfaces of a donut-like glass substrate 51 as a medium substrate.

As the magnetic layer, it is possible to use a so-called perpendicular double-layered medium having a perpendicular magnetic recording layer on a soft magnetic (backing) layer.

As the soft magnetic (backing) layer, materials containing, e.g., Fe, Ni, and Co can be used. Examples of the materials are FeCo-based alloys such as FeCo and FeCoV, FeNi-based alloys such as FeNi, FeNiMo, FeNiCr, and FeNiSi, FeAl-based alloys, FeSi-based alloys such as FeAl, FeAlSi, FeAlSiCr, FeAlSiTiRu, and FeAlO, FeTa-based alloys such as FeTa, FeTaC, and FeTaN, and FeZr-based alloys such as FeZrN.

The perpendicular magnetic recording layer can contain Co as a main component and can also contain Pt. It i's also possible to use a material further containing an arbitrary oxide. As the oxide, it is possible to select particularly silicon oxide or titanium oxide.

Magnetic grains (magnetic crystal grains) can be dispersed in the perpendicular magnetic recording layer. The magnetic grain can have a columnar structure vertically extending through the perpendicular magnetic recording layer. This structure can improve the orientation and crystallinity of the magnetic grains in the perpendicular magnetic recording layer. Consequently, a signal-to-noise ratio suited to high-density recording can be obtained. To obtain this structure, the amount of oxide to be contained is important. The content of oxide can be 3 to 12 mol %, and can also be 5 to 10 mol % of the total amount of Co, Cr, and Pt. When the content of oxide in the perpendicular magnetic recording layer falls within the above range, the oxide deposits around the magnetic grains when the layer is formed. This makes it possible to more favorably isolate and reduce the size of the magnetic grains.

The thickness of the perpendicular magnetic recording layer can be 5 to 60 nm, and can also be 10 to 40 nm. When the thickness of the perpendicular magnetic recording layer is in this range, the medium can operate as a magnetic recording/reproduction apparatus more suitable for high-density recording. If the thickness of the perpendicular magnetic recording layer is less than 5 nm, the reproduction output is too low, and the noise component often becomes higher than the reproduction output. If the thickness of the perpendicular magnetic recording layer exceeds 40 nm, the reproduction output becomes too high and often distorts the waveform.

The magnetic layer 52 on one surface of the glass substrate 51 was spin-coated, so as not to cover the central hole, with an ultraviolet-curable resin (to be referred to as a 2P resin hereinafter) having a viscosity of 5 cps, and the 2P resin was spread at a rotational speed of 10,000 rpm for 30 seconds, thereby forming a 2P resin layer 61 having a thickness T1 of 60 nm.

As shown in FIG. 3B, a first transparent resin stamper 71 having three-dimensional patterns was prepared.

In a vacuum chamber 81, one surface of the glass substrate 51 and the pattern surface of the first transparent stamper 71 were bonded via the 2P resin layer 61 in a vacuum ambient at 10³ Pa or less.

As shown in FIG. 3C, the vacuum was released, and the 2P resin layer 61 was cured by UV radiation through the first transparent stamper 71 at an atmospheric pressure. Although the time required for curing depends on the curing characteristics of a polymerization initiator contained in the 2P resin used and the ability of a UV light source, the resin is normally curable for a few tens of seconds.

As shown in FIG. 3D, the first transparent stamper 71 was separated from the glass substrate 51, thereby forming a 2P resin layer 61 onto which the three-dimensional patterns were transferred. A thickness T2 of the 2P resin layer 61 remaining in recesses was 30 nm.

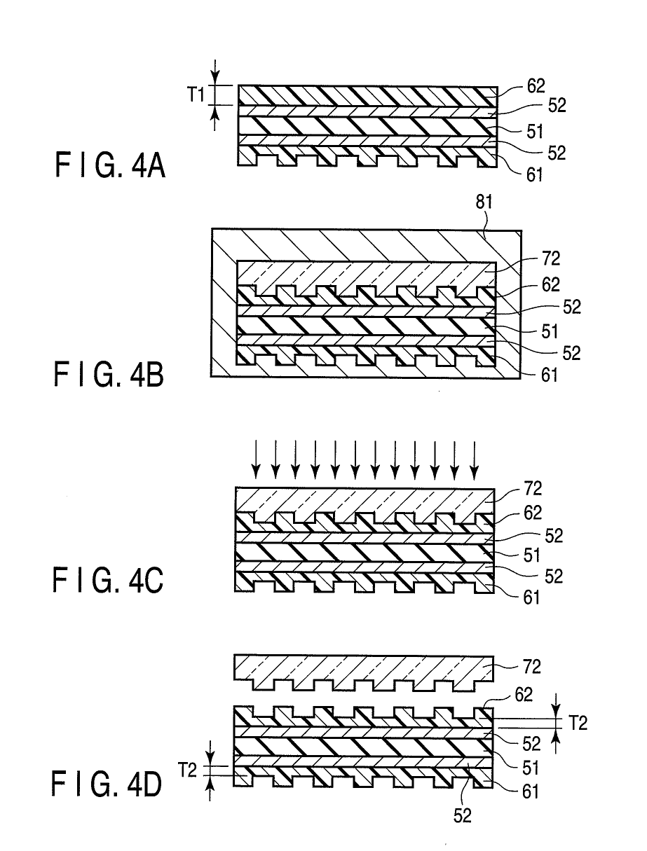

As shown in FIG. 4A, the magnetic layer 52 preformed on the other surface of the glass substrate 51 was spin-coated, so as not to cover the central hole, with a 2P resin having a viscosity of 5 cps, and the 2P resin was spread at a rotational speed of 10,000 rpm for 30 seconds, thereby forming a 2P resin layer 62 having a thickness T1 of 60 nm.

As shown in FIG. 4B, a second transparent resin stamper 72 having three-dimensional patterns was prepared. In the vacuum chamber 81, the other surface of the glass substrate 51 and the pattern surface of the second transparent stamper 72 were bonded via the 2P resin layer 62 in a vacuum ambient at 10³ Pa or less.

As shown in FIG. 4C, the vacuum wave released, and the 2P resin layer 62 was cured by UV radiation through the second transparent stamper 72 at an atmospheric pressure.

As shown in FIG. 4D, the second transparent stamper 72 was separated from the glass substrate 51, thereby forming a 2P resin layer 62 onto which the three-dimensional patterns were transferred. A thickness T2 of the 2P resin layer 62 remaining in recesses was 30 nm.

Note that although the glass substrate was coated with the 2P resin in this example, it is also possible to coat the pattern surface of the transparent stamper with the 2P resin, or coat both the glass substrate and transparent stamper with the 2P resin.

Then, the residue of the 2P resin was removed by means of reactive ion etching (RIE) using gaseous oxygen. Subsequently, an etching mask used to remove the residue produced in the imprinting step was used to process the magnetic material by etching (Ar ion milling) by means of an Ar ion beam. After that, the 2P resin was removed, and projections and recesses were covered with a nonmagnetic material. Etch back was performed until a carbon protective film on the magnetic film was exposed, and a C protective film was formed after that. In this manner, a magnetic recording medium was manufactured.

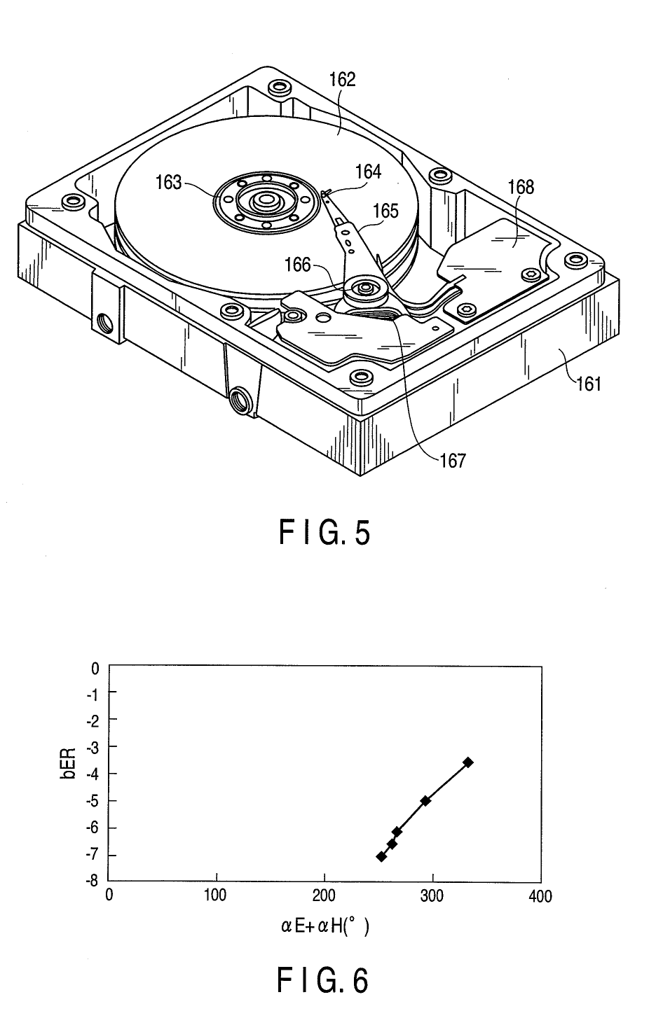

FIG. 5 is a view showing a magnetic recording/reproduction apparatus for performing recording and reproduction on the magnetic recording medium.

This magnetic recording apparatus includes, in a housing 61, a magnetic recording medium 62, a spindle motor 63 for rotating the magnetic recording medium 62, a head slider 64 including a recording/reproduction head, a head suspension assembly (a suspension 65 and actuator arm 66) for supporting the head slider 64, a voice-coil motor 67, and a circuit board.

The magnetic recording medium 62 is attached to and rotated by the spindle motor 63, and various digital data are recorded by the perpendicular magnetic recording method. The magnetic head incorporated into the head slider 64 is a so-called composite head, and includes a write head having a single-pole structure and a read head using a GMR or TMR film. The suspension 65 is held at one end of the actuator arm 66, and supports the head slider 64 so as to oppose it to the recording surface of the magnetic recording medium 62. The actuator arm 66 is attached to a pivot 68. The voice-coil motor 67 is formed as an actuator at the other end of the actuator arm 64. The voice-coil motor 67 drives the head suspension assembly to position the magnetic head in an arbitrary radial position of the magnetic recording medium 62. The circuit board includes a head IC, and generates a voice-coil motor driving signal, and control signals for controlling read and write by the magnetic head. This magnetic disk apparatus was used to record information on the processed magnetic recording medium, and measure the bit error rate of a reproduction signal.

### EXAMPLE 1

The Ni stamper A for use in injection molding was tested by the above-mentioned testing apparatus.

Consequently, (αE+αH)=255° smaller than 270°.

The AFM results of this stamper were a land width of 37 nm and a groove depth of 41 nm.

The land width is defined as a width at half of the land height.

Also, a land is a portion to be etched after being transferred onto a magnetic recording medium.

A magnetic recording medium was formed as follows by means of this stamper.

A glass substrate (amorphous substrate MEL3 2.5 inches in diameter manufactured by MYG) was placed in a film formation chamber of a DC magnetron sputtering apparatus (C-3010 manufactured by ANELVA), and the film formation chamber was evacuated until the vacuum degree reached 1×10⁻⁵ Pa.

A 100-nm-thick 90 at % Co-5 at % Zr-5 at % Nb film as a soft magnetic layer and a 20-nm-thick Ru film were formed on the substrate, thereby forming a soft magnetic backing layer.

Then, a 5-nm-thick (86 at % Co-14 at % Ir)-8 mol % SiO₂ film was formed as an underlying layer, and a 15-nm-thick 78 at % Co-6 at % Cr-16 at % Pt-8 mol % SiO₂ film was formed as a perpendicular magnetic recording layer.

In addition, the perpendicular magnetic recording layer was coated with the 2P resin as described above. A magnetic recording medium was formed by transferring patterns as described previously by means of the transparent stamper A, and the recording characteristic was evaluated using a hard disk drive. As a result, the bit error rate (bER) was −7 digits, i.e., a favorable result was obtained. Note that in this example, the bit error rate is defined as favorable when it is −6 digits or less when measured in the track center.

### EXAMPLE 2

The Ni stamper B for use in injection molding was tested by the above-mentioned testing apparatus.

As a result, (αE+αH)=265°.

The AFM results of this stamper were a land width of 39 nm and a groove depth of 41 nm.

A magnetic recording medium was formed by means of this stamper, and the recording characteristic was evaluated using a hard disk drive (HDD). Consequently, the bit error rate (bER) was −6.5 digits, i.e., a favorable result was obtained.

### EXAMPLE 3

The Ni stamper C for use in injection molding was tested by the above-mentioned testing apparatus.

As a result, (αE+αH)=270°.

The AFM results of this stamper were a land width of 40 nm and a groove depth of 41 nm.

A magnetic recording medium was formed by means of this stamper, and the recording characteristic was evaluated using a hard disk drive (HDD). Consequently, the bit error rate (bER) was −6.1 digits, i.e., a favorable result was obtained.

### COMPARATIVE EXAMPLE

The Ni stamper D for use in injection molding was tested by the above-mentioned testing apparatus.

As a result, (αE+αH)=335°.

The AFM results of this stamper were a land width of 50 nm and a groove depth of 43 nm.

A magnetic recording medium was formed by means of this stamper, and the recording characteristic was evaluated using a hard disk drive (HDD). Consequently, the bit error rate (bER) was −3.5 digits, i.e., an unfavorable result was obtained.

FIG. 6 collectively shows the above results.

FIG. 6 is a graph showing the relationship between the sum of the phases αE and αH by which the differential signal level of the E- and H-polarized components of the reflected light is maximum, and the bit error rate.

FIG. 6 reveals that the bER is −6 digits or less when (αE+αH)≦270°.

Also, evaluating the stamper groove shape by means of this testing apparatus is better than simply defining the stamper groove shape by the land width obtained by the AFM, because an optical difference appears regardless of the land shape in the former case.

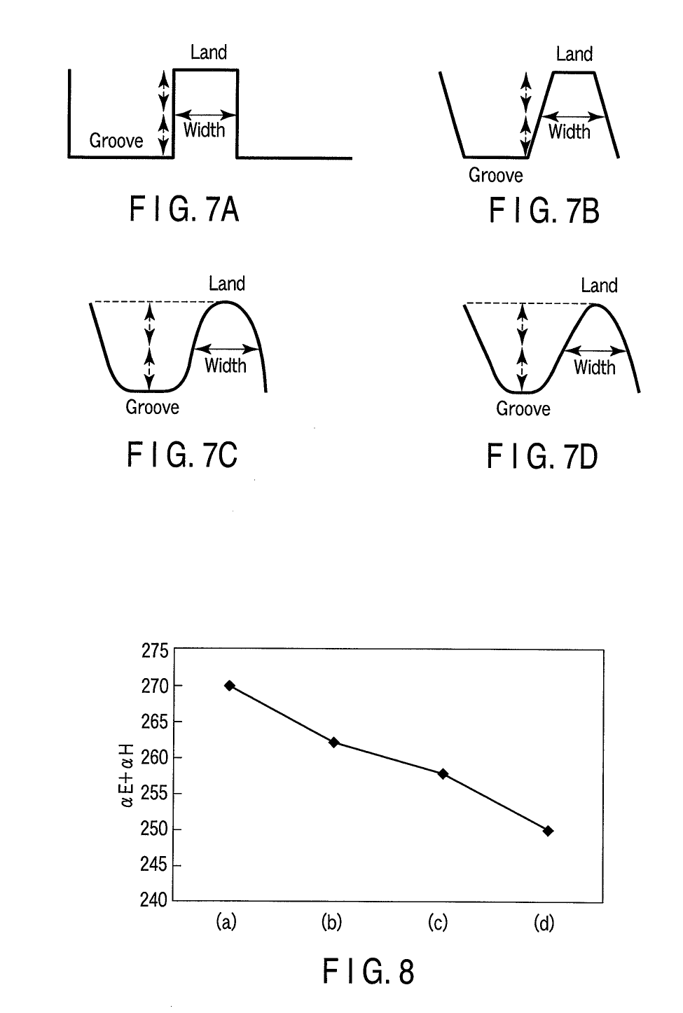

FIGS. 7A to 7D are model views showing the sections of various groove shapes having the same land width when measured by the same AFM. These grooves shown in FIGS. 7A to 7D can be defined as having the same land width, but obviously have different shapes. Accordingly, magnetic recording media having these grooves may have different recording characteristics. Note that the groove shape herein mentioned is a sectional shape obtained when three-dimensional track patterns formed on a disk-like recording medium are cut in the radial direction. A uniform groove shape means that the sectional shape is uniform regardless of the position in a track pattern. As shown in, e.g., FIG. 7B or 7C, an optimum groove shape is a shape in which the angle the land makes with the groove is smaller than a right angle, and the groove and land have bottom surfaces. When the angle is a right angle as shown in FIG. 7A, good recoding characteristics are presumably obtained. However, when the present inventors conducted experiments, transfer errors readily occurred during pattern transfer.

FIG. 8 is a graph showing the results of stamper groove shape evaluation performed on the stampers shown in FIGS. 7A to 7D.

FIG. 8 reveals that the evaluation results were different even for the same groove width (39 nm in this experiment) and the same groove depth (40 nm in this experiment).

The above results also indicate that the recording characteristics of a magnetic recording medium can be maintained by performing a test by the testing method of this example.

The method of manufacturing the discrete-track magnetic recording medium including the data area and servo area by means of the present invention has been explained above. However, the method of the present invention is not limited to this, and also applicable to the manufacture of optical disks such as a CD and DVD.

Although the embodiments of the present invention have been explained above, the present invention can be variously changed within the spirit and scope of the invention described in the scope of the appended claims. Also, the present invention can be variously modified when practiced without departing from the spirit and scope of the invention. Furthermore, various inventions can be made by appropriately combining a plurality of constituent elements disclosed in the above embodiments.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A stamper comprising either a concentric three-dimensional pattern or a spiral three-dimensional pattern, configured to form a track pattern on a surface of a recording layer of a recording medium comprising a data area and a servo area,
wherein a first phase αE and a second phase αH, at which a differential signal level of E- and H-polarized light components of reflected light becomes substantially maximum, are calculated when the three-dimensional pattern of the stamper corresponding to the data area of the recording medium is irradiated with the E- and H-polarized light components of linearly polarized light with a laser beam, and the first phase αE and the second phase αH satisfy a relationship represented by
(αE+αH)≦
270°

2. The stamper of claim 1, wherein the stamper is configured to transfer a transfer pattern onto a surface of a resist layer of the recording medium by printing.

3. A method of testing a groove shape of either a concentric three-dimensional pattern or a spiral three-dimensional pattern on a stamper for forming a track pattern on a surface of a recording layer of a recording medium comprising a data area and a servo area, comprising:
irradiating a data portion of the stamper with the E- and H-polarized components of linearly polarized light by a semiconductor laser, and measuring a voltage of a differential signal of reflected light by changing a phase; and
obtaining a first phase αE and a second phase αH at which difference signal voltages of the E- and the H-polarized light are maximum respectively, and determining the quality of the groove shape from the sum (αE+αH).

4. An apparatus for testing a groove shape of either a concentric three-dimensional pattern or a spiral three-dimensional pattern on a stamper for forming a track pattern on a surface of a recording layer of a recording medium comprising a data area and a servo area, comprising:
a measurement module configured to irradiate a data portion of the stamper with the E- and H-polarized components of linearly polarized light by a semiconductor laser, and to measure a voltage of a differential signal of reflected light by changing a phase; and
a determination module configured to obtain a first phase αE and a second phase αH at which difference signal voltages of the E- and H-polarized light are maximum, and to determine the quality of the groove shape from the sum (αE+αH).
